(19) United States
(12) Patent Application Publication
(10) Pub. No.: US 2010/0117687 A1
(43) Pub. Date: May 13, 2010

(54) TRACK AND HOLD CIRCUITS FOR AUDIO SYSTEMS AND OEPRATIONAL METHODS THEREOF

(75) Inventor: LANCE M. WONG, San Francisco, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: NUVOTON TECHNOLOGY CORPORATION, Hsin-Chu (TW)

(21) Appl. No.: 12/267,553

(22) Filed: Nov. 7, 2008

(51) Int. Cl. H03K 5/00

(52) U.S. Cl. 327/94

(57) ABSTRACT

A track and hold circuit includes an operational amplifier having first and second input ends and first and second output ends. A first capacitor has a first end and a second end operably coupled with the first input end and the first output end of the operational amplifier, respectively, wherein the second end of the first capacitor is switchably coupled with a first input voltage (Vᵢₙₚ). A second capacitor has a first end and a second end operably coupled with the second input end and the second output end of the operational amplifier, respectively, wherein the second end of the second capacitor is switchably coupled with a second input voltage (Vᵢₙₙ). A medium voltage (V_{MID}) providing means selectively provides a voltage substantially equal to (Vᵢₙₚ+Vᵢₙₙ)/2, wherein the first ends of the first capacitor and second capacitor are operably coupled with the V_{MID} providing means.

### FIELD OF THE INVENTION

The present invention relates to electronic circuit techniques. More particularly, the present invention relates to track and hold circuits for audio systems and operational methods thereof.

### BACKGROUND OF THE INVENTION

Track and hold circuits are used for capturing and holding voltage amplitude values of a continuous time input signal at predetermined times. In a typical application, a track and hold circuit holds voltage values at predetermined times or intervals and an analog-to-digital converter samples the held voltage values at the output of the track and hold circuit and converts the held values into digital signals. Conceptually, a track and hold circuit includes a switch and an amplitude storage device. In the track mode, the switch is closed thereby coupling the input signal to the storage device, and thereby allowing the amplitude storage device to follow or track the input signal. In the hold mode, the switch is open, which isolates the storage device from the input signal, and allows the storage device to hold constant the amplitude value of the input signal at the time the switch was opened.

FIG. 1 is a drawing showing a conventional track and hold circuit. In FIG. 1, a track and hold circuit 100 consists of an operational amplifiers 110, capacitors 120, 130, and switches 103, 105, 113, 115, 123, 125, 133, and 135. The switches 103, 105, 123, and 125 are controlled by a clock. The switches 113, 115, 133, and 135 are controlled by another clock. During the track mode, the switches 103, 105, 123, and 125 are closed and the switches 113, 115, 133, and 135 are opened, such that the capacitors 120, 130 are charged. During the hold mode, the switches 103, 105, 123, and 125 are opened and the switches 113, 115, 133, and 135 are closed, such that the charges stored on the capacitors 120, 130 are redistributed. As noted, a medium voltage (V_{MID}) is fixed at 1.65V.

It is found that an abrupt change of input voltages Vᵢₙₚ and Vᵢₙₙ, such as from 1.65V to 0.825V, may fail the operation of the operational amplifier 110 which in turn results in the failure of the operation of the track and hold circuit 100.

From the foregoing, improvements of the conventional track and hold circuit 100 are desired.

### BRIEF SUMMARY OF THE INVENTION

Embodiments of the present invention relate to audio systems, track and hold circuits, and operational methods thereof to eliminate the issue described above. In embodiments, a medium voltage (V_{MID}) providing means provides and applies a selected voltage from a group of voltages. The selected voltage is substantially equal to (Vᵢₙₚ+Vᵢₙₙ)/2, such that the operational amplifier having a PMOS input pair can desirably function.

In one embodiment, a track and hold circuit includes an operational amplifier having first and second input ends and first and second output ends. A first capacitor has a first end and a second end operably coupled with the first input end and the first output end of the operational amplifier, respectively, wherein the second end of the first capacitor is switchably coupled with a first input voltage (Vᵢₙₚ). A second capacitor has a first end and a second end operably coupled with the second input end and the second output end of the operational amplifier, respectively, wherein the second end of the second capacitor is switchably coupled with a second input voltage (Vᵢₙₙ). A medium voltage (V_{MID}) providing means selectively provides a voltage substantially equal to (Vᵢₙₚ+Vᵢₙₙ)/2, wherein the first ends of the first capacitor and second capacitor are operably coupled with the V_{MID} providing means.

In an alternative, the V_{MID} providing means includes a first V_{MID} voltage coupled with a first buffer and a second V_{MID} voltage coupled with a second buffer.

In another embodiment, the first V_{MID} voltage is about 1.65 V and the second V_{MID} voltage is about 0.825 V.

In the other embodiment, the first V_{MID} voltage is selectively coupled with the first ends of the first capacitor and the second capacitor via a first switch.

In an alternative, the second V_{MID} voltage is selectively coupled with the first ends of the first capacitor and the second capacitor via a first switch.

In still another embodiment, the first and second buffers are direct current (DC) buffers.

In one embodiment, an audio system includes a track and hold circuit. In an embodiment, the track and hold circuit can be coupled with an output driver, which in turn can be coupled with a speaker. The track and hold circuit includes an operational amplifier having first and second input ends and first and second output ends. A first capacitor has a first end and a second end operably coupled with the first input end and the first output end of the operational amplifier, respectively, wherein the second end of the first capacitor is switchably coupled with a first input voltage (Vᵢₙₚ). A second capacitor has a first end and a second end operably coupled with the second input end and the second output end of the operational amplifier, respectively, wherein the second end of the second capacitor is switchably coupled with a second input voltage (Vᵢₙₙ). A medium voltage (V_{MID}) providing means operably provides a voltage substantially equal to (Vᵢₙₚ+Vᵢₙₙ)/2, wherein the first ends of the first capacitor and second capacitor are operably coupled with the V_{MID} providing means.

In an alternative, the V_{MID} providing means includes a first V_{MID} voltage coupled with a first buffer and a second V_{MID} voltage coupled with a second buffer.

In another embodiment, the first V_{MID} voltage is about 1.65 V and the second V_{MID} voltage is about 0.825 V.

In the other embodiment, the first V_{MID} voltage is selectively coupled with the first ends of the first capacitor and the second capacitor via a first switch.

In still the other embodiment, the second V_{MID} voltage is selectively coupled with the first ends of the first capacitor and the second capacitor via a first switch.

In an alternative, the first and second buffers are direct current (DC) buffers.

In another embodiment, the audio system includes a controller selecting one of the first V_{MID} voltage and the second V_{MID} voltage.

In one embodiment, a method for operating a track and hold circuit is provided. The track and hold circuit includes an operational amplifier having first and second input ends and first and second output ends. A first capacitor has a first end and a second end operably coupled with the first input end and the first output end of the operational amplifier, respectively, wherein the second end of the first capacitor is switchably coupled with a first input voltage (Vᵢₙₚ). A second capacitor has a first end and a second end operably coupled with the second input end and the second output end of the operational amplifier, respectively, wherein the second end of the second capacitor is switchably coupled with a second input voltage (Vᵢₙₙ). A medium voltage (V_{MID}) providing means provides a V_{MID} voltage, wherein the first ends of the first capacitor and second capacitor are operably coupled with the V_{MID} providing means. The method includes coupling the first input voltage (Vᵢₙₚ) with the second end of the first capacitor. The second input voltage (Vᵢₙₙ) is coupled with the second end of the second capacitor. The first capacitor and the second capacitor are isolated from the operational amplifier. The first ends of the first capacitor and the second capacitor are coupled with the V_{MID} providing means. A first V_{MID} voltage is selected from a plurality of V_{MID} voltages, wherein the first V_{MID} voltage is substantially equal to (Vᵢₙₚ+Vᵢₙₙ)/2.

These and other embodiments of the invention along with many of its advantages and features are described in more detail in conjunction with the text below and attached figures It should be understood, however, that the invention is not limited to the precise arrangements and instrumentalities shown.

### BRIEF DESCRIPTION OF THE DRAWINGS

A further understanding of the nature and advantages of the present invention may be realized by reference to the remaining regions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 shows a conventional track and hold circuit.

FIG. 2A is a schematic drawing illustrating an equivalent circuit of a conventional track and hold circuit during a sampling phase.

FIG. 2B is a schematic drawing illustrating an equivalent circuit of a conventional track and hold circuit during a charge redistribution phase.

FIG. 2C is a regional schematic drawing of an operational amplifier including a PMOS input pair.

FIG. 3 is a simplified schematic drawing showing an exemplary track and hold circuit according to an embodiment of the present invention.

FIG. 4 is a simplified block diagram showing an exemplary audio system according to an embodiment of the present invention.

### DETAILED DESCRIPTION OF THE INVENTION

Embodiments of the present invention relate to audio systems, track and hold circuits, and methods thereof, using a medium voltage (V_{MID}) providing means that can provides a selected V_{MID} voltage following the change of the common mode input voltages. For example, a 0.825V-V_{MID} voltage is selected if the common mode input voltages are changed from 1.65V to 0.825V. By selecting the V_{MID} voltage that is substantially equal to the average of the common mode input voltages, the track and hold circuit can perform desired function. Though the exemplary track and hold circuits are applied to audio systems, the scope of the invention is not limited thereto.

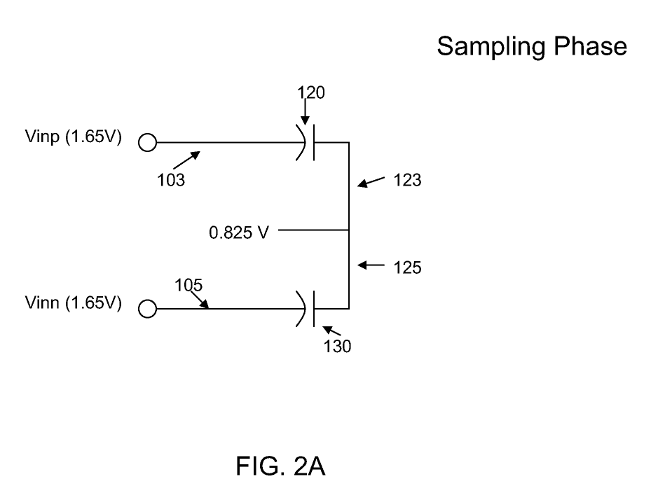

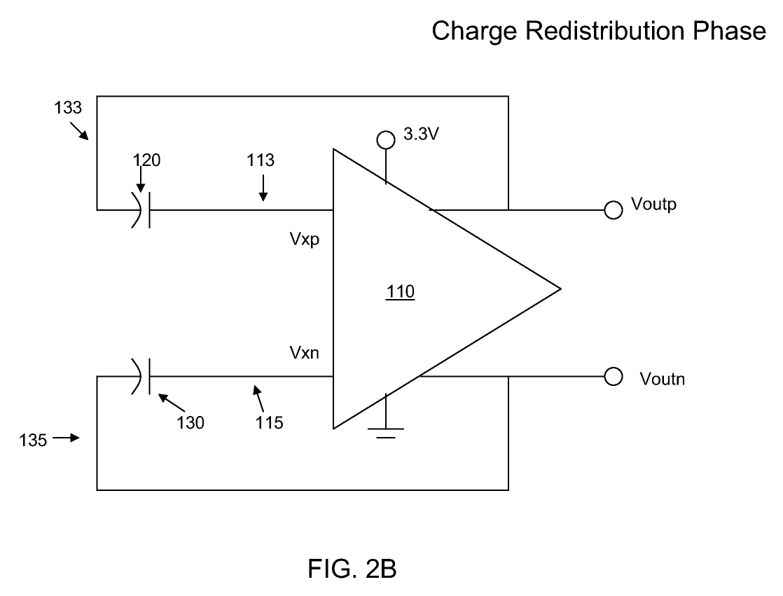

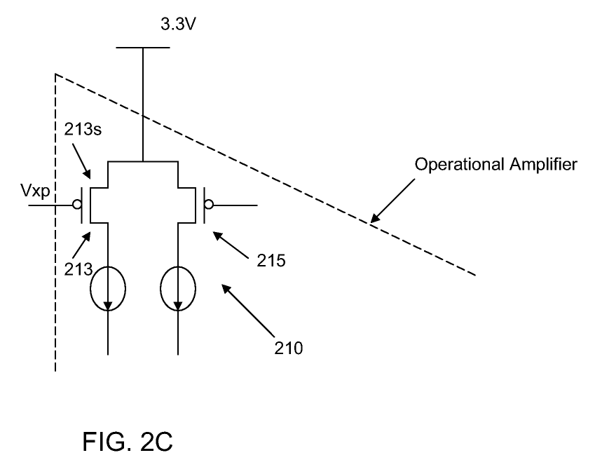

As noted, the conventional track and hold circuit 100 having a fixed V_{MID} voltage, i.e., 1.65V, can result in failure of the operation thereof. Following is the description of the operation of the conventional track and hold circuit, when the common mode voltages of the common mode input voltages Vᵢₙₚ and Vᵢₙₙ are changed from 1.65V to 0.825V. FIG. 2A is a schematic drawing illustrating an equivalent circuit of a conventional track and hold circuit during a sampling phase.

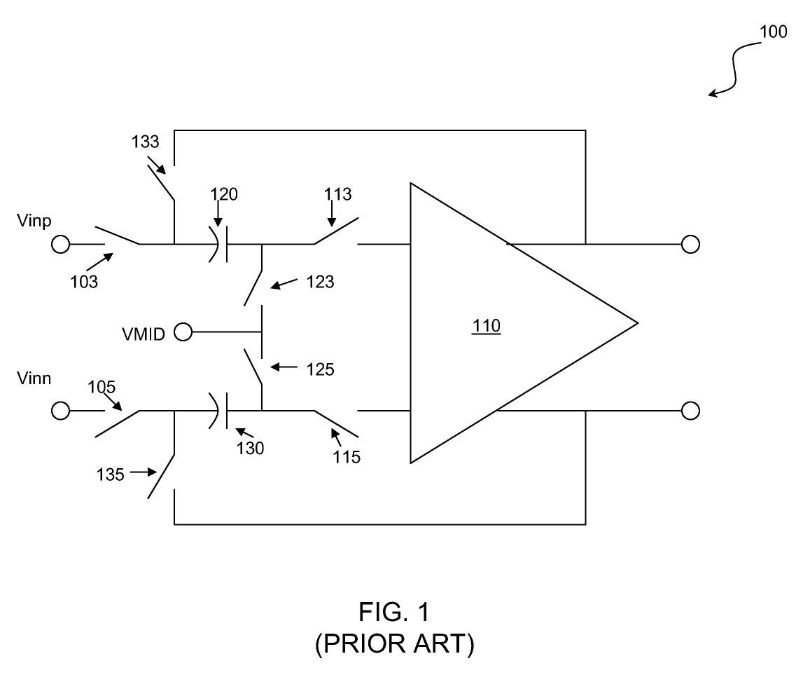

In conventional operation, the V_{MID} voltage is fixed at 1.65V and the common mode input voltages Vᵢₙₚ and Vᵢₙₙ are 1.65V. During the sampling phase, the switches 103, 105, 123, and 125 (shown in FIG. 1) are controlled to close by a first clock (not shown). The switches 113, 115, 133, and 135 (shown in FIG. 1) are controlled to open by a second clock (not shown). The captured charges on the capacitors 120, 130 thus are

$$\begin{matrix}{Q}_{tot} = C ( {V}_{MID} - {V}_{inp} ) + C ( {V}_{MID} - {V}_{inn} ) \\ = C ( 1.65 V - 1.65 V ) + C ( 1.65 V - 1.65 V ) \\ = 0 ,\end{matrix}$$

wherein C represents the capacitances of the capacitors 120, 130.

During the charge redistribution phase, the switches 103, 105, 123, and 125 (shown in FIG. 1) are controlled to open by the first clock (not shown). The switches 113, 115, 133, and 135 (shown in FIG. 1) are controlled to open by a second clock (not shown). The track and hold circuit during the charge redistribution phase is shown in FIG. 2B. As shown, the operational amplifier 110 is coupled with a voltage supply 3.3V and grounded, such that the output voltages Vₒᵤₜₚ and Vₒᵤₜₙ swing between 0 to 3.3V with respect to the medium value 1.65V. Under charge conservation, the output voltages Vₒᵤₜₚ and Vₒᵤₜₙ are 1.65V and the captured charges

$$\begin{matrix}{Q}_{tot} = 0 \\ = C ( {V}_{xp} - {V}_{outp} ) + C ( {V}_{xn} - {V}_{outn} ) \\ = C ( {V}_{xp} - 1.65 V ) + C ( {V}_{xn} - 1.65 V )\end{matrix}$$

Accordingly, the input voltages Vₓₚ and Vₓₙ of the operational amplifier 110 are 1.65V. The operation of the track and hold circuit 100 is normal.

It is found that when the common mode input voltages Vᵢₙₚ and Vᵢₙₙ are abruptly changed from 1.65V to a lower voltage, such as 0.825V, the track and hold circuit 100 can not function normally.

As noted, the top plates of the capacitors 120, 130 are coupled with the fixed voltage 1.65V for the conventional track and hold circuit 100. In the situation that the input common mold voltages Vᵢₙₚ and Vᵢₙₙ are 0.825V, the captured charges on the capacitors 120, 130 are

$$\begin{matrix}{Q}_{tot} = C ( {V}_{MID} - {V}_{inp} ) + C ( {V}_{MID} - {V}_{inn} ) \\ = C ( 1.65 V - 0.825 V ) + C ( 1.65 V - 0.825 V ) \\ = 1.65 C ,\end{matrix}$$

wherein C represents the capacitances of the capacitors 120, 130.

During the charge redistribution phase, the captured charges

$$\begin{matrix}{Q}_{tot} = 1.65 C \\ = C ( {V}_{xp} - {V}_{outp} ) + C ( {V}_{xn} - {V}_{outn} ) \\ = C ( {V}_{xp} - 1.65 V ) + C ( {V}_{xn} - 1.65 V )\end{matrix}$$

Accordingly, the Vₓₚ and Vₓₙ are equal to 2.475V.

FIG. 2C is a regional schematic drawing of an operational amplifier including a PMOS input pair. In FIG. 2C, a PMOS input pair 210 includes PMOS transistors 213, 215 coupled to current sources. The source 213s of the PMOS transistor 213 is coupled with the voltage supply 3.3V. The gate of the PMOS transistor 213 is coupled with Vₓₚ.

As noted, Vₓₚ is equal to 2.475V. Assumed that the voltage difference between source 213s and gate Vₓₚ to turn on the PMOS transistor 213 is about 1V, the voltage of the source 213s should be about 3.475V, which is higher than the voltage that the power supply (3.3V) can supply. The 3.3V power supply cannot turn on the PMOS transistor 213 and the operational amplifier therefore cannot desirably function. The track and hold circuit 100 shown in FIG. 1 thus perform the desired function when the common mode input voltages Vᵢₙₚ and Vᵢₙₙ shift to a low voltage, such as 0.825V.

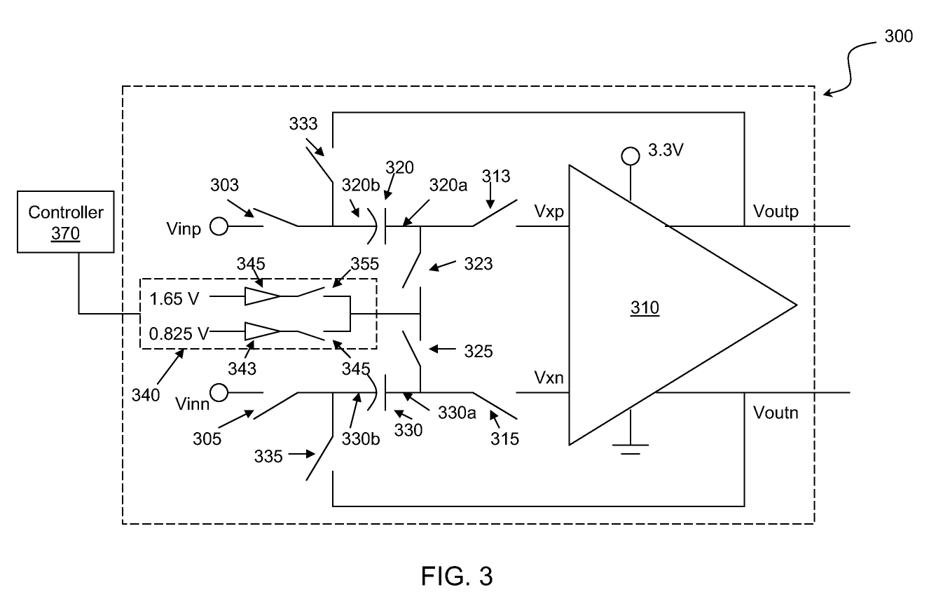

FIG. 3 is a simplified schematic drawing showing an exemplary track and hold circuit 300 according to an embodiment of the present invention. This diagram is merely an example, which should not unduly limit the scope of the claims herein. One of ordinary skill in the art would recognize other variations, modifications, and alternatives.

In embodiment, the track and hold circuit 300 can include an operational amplifier 310. The operational amplifier 310 can have first and second input ends and first and second output ends (not labeled). A first capacitor 320 has a first end 320a and a second end 320b. The first end 320a is operably coupled with the first input end of the operational amplifier 310 via a switch 313. The second end 320b is operably coupled with the first output end of the operational amplifier 310 via a witch 333. The second end 320b is also operable coupled with a first input voltage (Vᵢₙₚ) via a switch 303. A second capacitor 330 has a first end 330a and a second end 330b. The first end 330a is operably coupled with the second input end of the operational amplifier 310 via a switch 315. The second end 330b is operably coupled with the second output end of the operational amplifier 310 via a witch 335. The second end 330b is also operably coupled with a second input voltage (Vᵢₙₙ) via a switch 305. A medium voltage (V_{MID}) providing means 340 is operably coupled with the first ends 320a, 330a, e.g., top plates, of the capacitors 320, 330 via switches 323, 325, respectively. The V_{MID} providing means 340 is capable of selecting and providing a voltage substantially equal to (Vᵢₙₚ+Vᵢₙₙ)/2 in response to the changes of the common mode input voltages.

In embodiments, the V_{MID} providing means 340 can include a plurality of V_{MID} voltages, such as 1.65V and 0.825V. Each of the V_{MID} voltages can be coupled with a buffer 343 or 345. The buffers 343 and 345 can be coupled with the first ends 320a, 330a of the capacitors 320, 330 via switches 343, 355, respectively. It is noted that the number of the buffers and V_{MID} voltages are merely exemplary. The scope of the invention is not limited thereto.

Following is the description of an exemplary operation of the track and hold circuit according to the embodiment of the present invention. Referring to FIG. 3, for embodiments applying 1.65V to the common mode input voltages Vᵢₙₚ and Vᵢₙₙ, a controller 370 coupled with the V_{MID} providing means 340 can select and close the switch 355 and let the switch 345 open. That is, the 1.65V is applied as the V_{MID} voltage. During the sampling phase, the switches 303, 305, 323, and 325 are closed and switches 313, 315, 333, and 335 are opened. The captured charges Qₜₒₜ=C (1.65V−1.65V)+C (1.65V−1.65V)=0. During the charge redistribution phase, the switches 303, 305, 323, and 325 are opened and switches 313, 315, 333, and 335 are closed. Since Qₜₒₜ=0=C (Vₓₚ−1.65V)+C (Vₓₙ−1.65V), the Vₓₚ and Vₓₙ are equal to 1.65V.

In the embodiments using the PMOS input pair 210 (shown in FIG. 2C) in the operational amplifier 310, the Vₓₚ is 1.65V. Assumed that the voltage difference between the source 213s and the gate, i.e., Vₓₚ, for turning on the PMOS transistor 213 is about 1V, the voltage of the source 213s needs to be about 2.65V. Since the power supply is about 3.3V, the power supply (3.3V) is capable of driving the source 213s and turning on the PMOS transistor 213 and the operational amplifier 310 can desirably function.

In embodiments applying 0.825V to the common mode input voltages Vᵢₙₚ and Vᵢₙₙ, the controller 370 coupled with the V_{MID} providing means 340 can select and close the switch 345 and let the switch 355 open. That is, 0.825V is applied as the V_{MID} voltage. During the sampling phase, the switches 303, 305, 323, and 325 are closed and switches 313, 315, 333, and 335 are opened. The captured charges Qₜₒₜ=C (0.825V−0.825V)+C (0.825V−0.825V)=0. During the charge redistribution phase, the switches 303, 305, 323, and 325 are opened and switches 313, 315, 333, and 335 are closed. Qₜₒₜ=0=C (Vₓₚ−1.65V)+C (Vₓₙ−1.65V). Accordingly, the Vₓₚ and Vₓₙ are equal to 1.65V.

In embodiments using the PMOS input pair 210 (shown in FIG. 2C) in the operational amplifier 310, the Vₓₚ is 1.65V. Assumed that the voltage difference between the source 213s and the gate, i.e., Vₓₚ, for turning on the PMOS transistor 213 is about 1V, the voltage of the source 213s needs to be about 2.65V. Since the power supply is about 3.3V, the power supply voltage is capable of driving the source 213s of the PMOS transistor 213 and the operational amplifier 310 can desirably function.

From the foregoing, the track and hold circuit 300 includes the V_{MID} providing means 340, which can selectively provide V_{MID} voltages to the track and hold circuit 300 in response to the change of the common mode input voltages Vᵢₙₚ and Vᵢₙₙ. When the common mode input voltages Vᵢₙₚ and Vᵢₙₙ are changed from about 1.65V to about 0.825V, the input voltages Vₓₚ and Vₓₙ of the operational amplifier 310 can be maintained of about 2.3V or less, e.g., about 1.65V. The input voltages Vₓₚ and Vₓₙ are kept low such that the PMOS input pair 210 (shown in FIG. 2C) of the operational amplifier 310 (shown in FIG. 3) can be turned on and the operational amplifier 310 can desirably function.

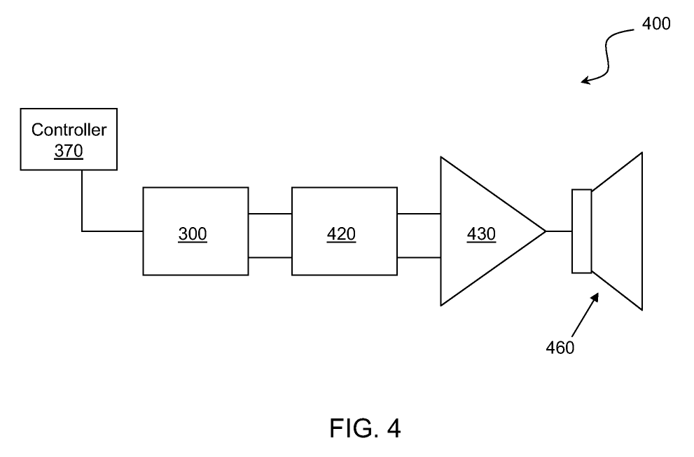

FIG. 4 is a simplified block diagram showing an exemplary audio system 400 according to an embodiment of the present invention. Referring to FIG. 4, audio system 400 can include a track and hold circuit 300 and controller 370. In an embodiment, the track and hold circuit is configured to perform digital to analog conversion. In an embodiment, as shown in FIG. 4, the track and hold circuit can drive a smoothing filter 420, which in turn can drive a speaker driver 430 coupled to a speaker 460. Of course, there can be other variations, modifications, and alternatives.

In a specific embodiment, track and hold circuit 300 and controller 370 in FIG. 4 can be similar to track and hold circuit 300 and controller 370 discussed above in connection with FIG. 3. The track and hold circuit includes an operational amplifier having first and second input ends and first and second output ends. A first capacitor has a first end and a second end operably coupled with the first input end and the first output end of the operational amplifier, respectively, wherein the second end of the first capacitor is switchably coupled with a first input voltage (Vᵢₙₚ). A second capacitor has a first end and a second end operably coupled with the second input end and the second output end of the operational amplifier, respectively, wherein the second end of the second capacitor is switchably coupled with a second input voltage (Vᵢₙₙ). A medium voltage (V_{MID}) providing means operably provides a voltage substantially equal to (Vᵢₙₚ+Vᵢₙₙ)/2, wherein the first ends of the first capacitor and second capacitor are operably coupled with the V_{MID} providing means.

Having described several embodiments, it will be recognized by those of skill in the art that various modifications, alternative constructions, and equivalents may be used without departing from the spirit of the invention. Additionally, a number of well known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a method” includes a plurality of such methods and reference to “the precursor” includes reference to one or more precursors and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A track and hold circuit, comprising:
an operational amplifier having first and second input ends and first and second output ends;
a first capacitor having a first end and a second end operably coupled with the first input end and the first output end of the operational amplifier, respectively, wherein the second end of the first capacitor is switchably coupled with a first input voltage (Vᵢₙₚ);
a second capacitor having a first end and a second end operably coupled with the second input end and the second output end of the operational amplifier, respectively, wherein the second end of the second capacitor is switchably coupled with a second input voltage (Vᵢₙₙ); and
a medium voltage (V_{MID}) providing means selectively providing a voltage substantially equal to (Vᵢₙₚ+Vᵢₙₙ)/2, wherein the first ends of the first capacitor and second capacitor are operably coupled with the V_{MID} providing means.

2. The track and hold circuit of claim 1, wherein the V_{MID} providing means includes a first V_{MID} voltage coupled with a first buffer and a second V_{MID} voltage coupled with a second buffer.

3. The track and hold circuit of claim 2, wherein the first V_{MID} voltage is about 1.65 V and the second V_{MID} voltage is about 0.825 V.

4. The track and hold circuit of claim 2, wherein the first V_{MID} voltage is selectively coupled with the first ends of the first capacitor and the second capacitor via a first switch.

5. The track and hold circuit of claim 2, wherein the second V_{MID} voltage is selectively coupled with the first ends of the first capacitor and the second capacitor via a first switch.

6. The track and hold circuit of claim 2, wherein the first and second buffers are direct current (DC) buffers.

7. An audio system comprising:
a speaker;
an output driver, and
a track and hold circuit coupled with the output driver, the track and hold circuit including:
an operational amplifier having first and second input ends and first and second output ends;
a first capacitor having a first end and a second end operably coupled with the first input end and the first output end of the operational amplifier, respectively, wherein the second end of the first capacitor is switchably coupled with a first input voltage (Vᵢₙₚ);
a second capacitor having a first end and a second end operably coupled with the second input end and the second output end of the operational amplifier, respectively, wherein the second end of the second capacitor is switchably coupled with a second input voltage (Vᵢₙₙ); and
a medium voltage (V_{MID}) providing means selectively providing a voltage substantially equal to (Vᵢₙₚ+Vᵢₙₙ)/2, wherein the first ends of the first capacitor and second capacitor are operably coupled with the V_{MID} providing means.

8. The audio system of claim 7, wherein the V_{MID} providing means includes a first V_{MID} voltage coupled with a first buffer and a second V_{MID} voltage coupled with a second buffer.

9. The audio system of claim 8, wherein the first V_{MID} voltage is about 1.65 V and the second V_{MID} voltage is about 0.825 V.

10. The audio system of claim 8, wherein the first V_{MID} voltage is selectively coupled with the first ends of the first capacitor and the second capacitor via a first switch.

11. The audio system of claim 8, wherein the second V_{MID} voltage is selectively coupled with the first ends of the first capacitor and the second capacitor via a first switch.

12. The audio system of claim 8, wherein the first and second buffers are direct current (DC) buffers.

13. The audio system of claim 8 further comprising a controller selecting one of the first V_{MID} voltage and the second V_{MID} voltage.

14. A method for operating a track and hold circuit, the track and hold circuit including an operational amplifier having first and second input ends and first and second output ends; a first capacitor having a first end and a second end operably coupled with the first input end and the first output end of the operational amplifier, respectively, wherein the second end of the first capacitor is switchably coupled with a first input voltage (Vᵢₙₚ); a second capacitor having a first end and a second end operably coupled with the second input end and the second output end of the operational amplifier, respectively, wherein the second end of the second capacitor is switchably coupled with a second input voltage (Vinn); and a medium voltage (V_{MID}) providing means, wherein the first ends of the first capacitor and second capacitor are operably coupled with the V_{MID} providing means, the method comprising:
coupling the first input voltage (Vᵢₙₚ) with the second end of the first capacitor;
coupling the second input voltage (Vᵢₙₙ) with the second end of the second capacitor;
isolating the first capacitor and the second capacitor from the operational amplifier;
coupling the first ends of the first capacitor and the second capacitor with the V_{MID} providing means; and
selecting a first V_{MID} voltage from a plurality of V_{MID} voltages, wherein the first V_{MID} voltage is substantially equal to (Vᵢₙₚ+Vᵢₙₙ)/2.

15. The method of claim 14, wherein the plurality of V_{MID} voltages comprise 0.825 V and 1.65 V.

16. The method of claim 15, wherein the first V_{MID} voltage is 0.825 V.

17. The method of claim 14, wherein selecting the first V_{MID} voltage comprises selecting and closing a switch coupled with the first V_{MID} voltage.

18. The method of claim 14 further comprising coupling the first V_{MID} voltage with a buffer.

19. The method of claim 18, wherein the buffer is a direct current (DC) buffer.

20. The method of claim 14, wherein the first input voltage (Vᵢₙₚ) and the second input voltage (Vᵢₙₙ) are common mode input voltages.
